(19) United States
(12) Patent Application Publication
(10) Pub. No.: US 2006/0214212 A1
(43) Pub. Date: Sep. 28, 2006

(54) SEMICONDUCTOR DEVICE AND METHOD OF MANUFACTURING SEMICONDUCTOR DEVICE

(75) Inventors: Katsuyuki HORITA, Tokyo (JP); Masato ISHIBASHI, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 11/277,186

(22) Filed: Mar. 22, 2006

(30) Foreign Application Priority Data
Mar. 23, 2005 (JP) 2005-083334
Feb. 22, 2006 (JP) 2006-044754

(51) Int. Cl. H01L 29/94

(52) U.S. Cl. 257/300

(57) ABSTRACT

First active region and second and third active regions are defined in a semiconductor substrate within a memory cell area and a logic circuit area, respectively. First to third MOS transistors are formed in the first to third active regions, respectively. As viewed from above, the length of the first and second active regions along the gate width is not greater than the length of the third active region along the gate width. In the isolation insulation film, the upper surface of a peripheral portion provided around the first active region is positioned below the upper surface thereof, and the upper surface of a peripheral portion provided around the second active region is positioned below the upper surface thereof. A gate electrode is formed on the upper surfaces of the first to third active regions and the side surfaces of the first and second active regions.

### BACKGROUND OF THE INVENTION

1. Field of the Invention

The present invention relates to a semiconductor device including a plurality of MOS transistors and a method of manufacturing the semiconductor device.

2. Description of the Background Art

Gate structures called the double-gate structure and the tri-gate structure have conventionally been proposed for achieving improved turn-on and turn-off characteristics of MOS transistors. Such gate structures have a gate electrode surrounding, from multiple directions, a semiconductor area in which a channel region for a MOS transistor is to be formed, thereby achieving improved controllability of the channel region by a gate voltage.

For instance, Fu-Liang Yang et al., “35 nm CMOS FinFETs” (2002 Symposium on VLSI Technology Digest of Technical Papers, p. 104) and Fu-Liang Yang et al., “5 nm-Gate Nanowire FinFETs” (2004 Symposium on VLSI Technology Digest of Technical Papers, p. 196) disclose a double-gate FinFET structure. These documents describe using an SOI (silicon on insulator) substrate on which MOS transistors are to be formed, and building up the Fin structure on a silicon layer formed on a buried oxide of the SOI substrate, thereby forming MOS transistors utilizing the Fin structure.

Japanese Patent Application Laid-Open No. 2003-124463 proposes a technique for achieving the double-gate structure without using a SOI wafer. In this technique, a projection extending out of an isolation insulation film is formed on a semiconductor substrate, and the projection is surrounded by a gate electrode to achieve the double-gate structure. Japanese Patent Application Laid-Open No. 7-86595 (1995) also discloses a technique related to the double-gate structure.

As a semiconductor device including a plurality of MOS transistors, one having a memory cell area in which a plurality of memory cells are formed and a logic circuit area in which a logic circuit is formed has conventionally been proposed. In such semiconductor device, MOS transistors of various dimensions are generally formed in the logic circuit area. Therefore, even when the technique disclosed in the above-mentioned JP2003-124463 is applied to the MOS transistors in the logic circuit area, advantages of the double- or tri-gate structure might not be exercised sufficiently depending on MOS transistors to be used. This causes problems such as an insufficient improvement in performance of the semiconductor device.

Further, in a semiconductor device including a plurality of MOS transistors, the plurality of MOS transistors can have different current drive capabilities by designing the MOS transistors to have different gate widths. However, to design a plurality of MOS transistors to have different gate widths, active regions in which the plurality of MOS transistors are to be formed need to have different widths, which results in a complicated mask pattern for use in a photolithography process. As a result, a sufficient process margin for the photolithography process may not be secured, and hence, the performance of the semiconductor device may not be secured sufficiently.

### SUMMARY OF THE INVENTION

An object of the present invention is to provide a technique of achieving improved performance of a semiconductor device including a plurality of MOS transistors.

A first aspect of the present invention is directed to a semiconductor device having a memory cell area in which a plurality of memory cells are formed and a logic circuit area in which a logic circuit is formed. The semiconductor device includes a semiconductor substrate, an isolation insulation film provided in an upper surface of the semiconductor substrate to define a first active region in the semiconductor substrate within the memory cell area and second and third active regions in the semiconductor substrate within the logic circuit area, and first to third MOS transistors provided in the first to third active regions, respectively. As viewed from above, a dimension of the first active region along a gate width of the first MOS transistor and a dimension of the second active region along a gate width of the second MOS transistor are smaller than a dimension of the third active region along a gate width of the third MOS transistor. As viewed from above, the dimension of the second active region is not greater than the dimension of the first active region. In the isolation insulation film within the memory cell area, a first-active-region peripheral portion provided around the first active region has an upper surface positioned below an upper surface of the first active region, and a first gate electrode is formed on an upper surface of part of the first active region and side surfaces of the part of the first active region facing each other along the gate width of the first MOS transistor. The part of the first active region projects upward from the upper surface of the first-active-region peripheral portion. A first gate insulation film is interposed between the first gate electrode and the upper and side surfaces of the part of the first active region. In the isolation insulation film within the logic circuit area, a second-active-region peripheral portion provided around the second active region has an upper surface positioned below an upper surface of the second active region, and a second gate electrode is formed on an upper surface of part of the second active region and side surfaces of the part of the second active region facing each other along the gate width of the second MOS transistor. The part of the second active region projects upward from the upper surface of the second-active-region peripheral portion. A second gate insulation film is interposed between the second gate electrode and the upper and side surfaces of the part of the second active region. The upper surface of the first-active-region peripheral portion and the upper surface of the second-active-region peripheral portion are positioned below an upper surface of a third-active-region peripheral portion provided around the third active region in the isolation insulation film within the logic circuit area.

A method of manufacturing the semiconductor device of the first aspect includes the following steps (a) to (c). The step (a) is to form an isolation insulation film in an upper surface of a semiconductor substrate to define a first active region in the semiconductor substrate within the memory cell area and second and third active regions in the semiconductor substrate within the logic circuit area. The step (b) is to etch down an upper surface of a first-active-region peripheral portion provided around the first active region in the isolation insulation film within the logic circuit area to be positioned below an upper surface of the first active region, as well as etching down an upper surface of a second-active-region peripheral portion provided around the second active region in the isolation insulation film within the logic circuit area to be positioned below an upper surface of the second active region, without etching down an upper surface of a third-active-region peripheral portion provided around the third active region in the isolation insulation film within the logic circuit area. The step (c) is to form first to third MOS transistors in the first to third active regions, respectively, after the step (b). In the step (a), the isolation insulation film is formed such that a dimension of the first active region in a first direction in which a gate width of the first MOS transistor is to extend and a dimension of the second active region in a second direction in which a gate width of the second MOS transistor is to extend are smaller than a dimension of the third active region in a third direction in which a gate width of the third MOS transistor is to extend and such that the dimension of the second active region is not greater than the dimension of the first active region. In the step (c), a first gate electrode is formed on an upper surface of part of the first active region and side surfaces of the part of the first active region facing each other in the first direction. The part of the first active region projects upward from the upper surface of the first-active-region peripheral portion by the execution of the step (b). A first gate insulation film is interposed between the first gate electrode and the upper and side surfaces of the part of the first active region, and a second gate electrode is formed on an upper surface of part of the second active region and side surfaces of the part of the second active region facing each other in the second direction. The part of the second active region projects upward from the upper surface of the second-active-region peripheral portion by the execution of the step (b). A second gate insulation film is interposed between the second gate electrode and the upper and side surfaces of the part of the second active region.

In the second active region in the logic circuit area, similarly to the first active region in the memory cell area, the gate electrode is formed on the upper surface and side surfaces of part of the second active region facing each other along the gate width that projects upward from the upper surface of the isolation insulation film, with the gate insulation film interposed therebetween. Therefore, the second MOS transistor formed in the second active region can be configured to have the double- or tri-gate structure. More specifically, according to the present invention, the structure applied to the first active region in the memory cell area is also applied to the second active region in the logic circuit area having a dimension along the gate width not greater than the dimension along the gate width of the first active region in the memory cell area, so that the second MOS transistor formed in the second active region has the tri- or double-gate structure. Generally, a layout pattern of a plurality of memory cells is generally configured with a repetitive pattern, and therefore, the degree of difficulty of a lithography process for forming the memory cells is low, and a plurality of active regions where the memory cells are formed can be arranged densely. Accordingly, the first active region in the memory cell area has a relatively small dimension along the gate width, and the second active region has a sufficiently small dimension along the gate width not greater than the relatively small dimension along the gate width of the first active region. In this manner, applying the same structure as the memory cell area to the second active region having a sufficiently small dimension along the gate width to achieve the double- or tri-gate structure in the second active region secures forming a channel region in the whole area of part of the second active region that projects upward from the upper surface of the isolation insulation film. This ensures improved turn-on and turn-off characteristics of the second MOS transistor formed on the second active region as well as reduced off-state leakage current in the whole device, which results in improved performance of the semiconductor device.

A second aspect of the present invention is directed to a semiconductor device including a semiconductor substrate, an isolation insulation film provided in an upper surface of the semiconductor substrate to define first and second active regions in the semiconductor substrate, and first and second MOS transistors provided in the first and second active regions, respectively. In the isolation insulation film, a first-active-region peripheral portion provided around the first active region has an upper surface positioned below an upper surface of the first active region, and a first gate electrode is formed on an upper surface of part of the first active region and side surfaces of the part of the first active region facing each other along a gate width of the first MOS transistor. The part of the first active region projects upward from the upper surface of the first-active-region peripheral portion. A first gate insulation film is interposed between the first gate electrode and the upper and side surfaces of the part of the first active region. In the isolation insulation film, a second-active-region peripheral portion provided around the second active region has an upper surface positioned below an upper surface of the second active region and the upper surface of the first-active-region peripheral portion, and a second gate electrode is formed on an upper surface of part of the second active region and side surfaces of the part of the second active region facing each other along a gate width of the second MOS transistor. The part of the second active region projects upward from the upper surface of the second-active-region peripheral portion. A second gate insulation film is interposed between the second gate electrode and the upper and side surfaces of the part of the second active region.

A method of manufacturing the semiconductor device of the second aspect includes the following steps (a) to (c). The step (a) is to form an isolation insulation film in an upper surface of a semiconductor substrate to define first and second active regions in the semiconductor substrate. The step (b) is to etch down an upper surface of a first-active-region peripheral portion provided around the first active region in the isolation insulation film to be positioned below an upper surface of the first active region, as well as etching down an upper surface of a second-active-region peripheral portion provided around the second active region in the isolation insulation film to be positioned below an upper surface of the second active region and the upper surface of the first-active-region peripheral portion. The step (c) is to form first and second MOS transistors in the first and second active regions, respectively, after the step (b). In the step (c), a first gate electrode is formed on an upper surface of part of the first active region and side surfaces of the part of the first active region facing each other along a gate width of the first MOS transistor. The part of the first active region projects upward from the upper surface of the first-active-region peripheral portion by the execution of the step (b). A first gate insulation film is interposed between the first gate electrode and the upper and side surfaces of the part of the first active region, and a second gate electrode is formed on an upper surface of part of the second active region and side surfaces of the part of the second active region facing each other along a gate width of the second MOS transistor. The part of the second active region projects upward from the upper surface of the second-active-region peripheral portion by the execution of the step (b). A second gate insulation is interposed between the second gate electrode and the upper and side surfaces of the part of the second active region.

In the isolation insulation film, the upper surface of the second-active-region peripheral portion is positioned below the upper surface of the first-active-region peripheral portion. Part of the second active region projecting from the isolation insulation film can thus be made larger than in the first active region. Accordingly, the channel region of the second MOS transistor formed in the second active region can be made greater in volume than the channel region of the first MOS transistor formed in the first active region. Therefore, even when setting the first and second active regions to have an equal dimension along their gate widths, the second MOS transistor can have a superior current drive capability than the first MOS transistor. As a result, the layout pattern can be simplified while forming a plurality of MOS transistors having different current drive capabilities, which ensures a sufficient process margin in a photolithography process. This results in improved performance of the semiconductor device.

Further, the gate width of the second active region along the gate width can be reduced while maintaining the current drive capability of the second MOS transistor, so that the size of the second active region can be reduced. This allows size reduction of the whole semiconductor device.

A third aspect of the present invention is directed to a semiconductor device having a first area in which a plurality of SRAM memory cells are formed and a second area in which an interface circuit is formed. The semiconductor device includes a semiconductor substrate, an isolation insulation film provided in an upper surface of the semiconductor substrate to define a first active region in the semiconductor substrate within the first area and a second active region in the semiconductor substrate within the second area, and first and second MOS transistors provided in the first and second active regions, respectively. In the isolation insulation film within the first area, a first-active-region peripheral portion provided around the first active region has an upper surface positioned below an upper surface of the first active region, and a first gate electrode is formed on an upper surface of part of the first active region and side surfaces of the part of the first active region facing each other along a gate width of the first MOS transistor. The part of the first active region projects upward from the upper surface of the first-active-region peripheral portion. A first gate insulation film is interposed between the first gate electrode and the upper and side surfaces of the part of the first active region. A second gate electrode is formed on an upper surface of the second active region with a second gate insulation film interposed therebetween. The upper surface of the first-active-region peripheral portion is positioned below an upper surface of a second-active-region peripheral portion provided around the second active region in the isolation insulation film within the second area.

A method of manufacturing the semiconductor device of the third aspect includes the following steps (a) to (c). The step (a) is to form an isolation insulation film in an upper surface of a semiconductor substrate to define a first active region in the semiconductor substrate within the first area and a second active region in the semiconductor substrate within the second area. The step (b) is to etch down an upper surface of a first-active-region peripheral portion provided around the first active region in the isolation insulation film within the first area to be positioned below an upper surface of the first active region, without etching down an upper surface of a second-active-region peripheral portion provided around the second active region in the isolation insulation film within the second area. The step (c) is to form first and second MOS transistors in the first and second active regions, respectively, after the step (b). In the step (c), a first gate electrode is formed on an upper surface of part of the first active region and side surfaces of the part of the first active region facing each other in a direction in which a gate width of the first MOS transistor is to extend. The part of the first active region projects upward from the upper surface of the first-active-region peripheral portion by the execution of the step (b). A first gate insulation film is interposed between the first gate electrode and the upper and side surfaces of the part of the first active region, and a second gate electrode is formed on the upper surface of the second active region with a second gate insulation film interposed therebetween.

The double- or tri-gate structure is not employed for the second MOS transistor for use in the interface circuit. This allows generation of a good-quality and highly-reliable gate insulation film.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing the structure of a semiconductor device according to a first preferred embodiment of the present invention;

FIG. 2 is a sectional view showing the structure of the semiconductor device according to the first preferred embodiment;

FIG. 3 is a circuit diagram of a memory cell according to the first preferred embodiment;

FIGS. 4 through 13 are sectional views showing a method of manufacturing the semiconductor device according to the first preferred embodiment in the order of steps;

FIG. 14 is a sectional view showing the structure of a semiconductor device to be compared with the semiconductor device according to the first preferred embodiment;

FIGS. 15 through 22 are sectional views showing a modified method of manufacturing the semiconductor device according to the first preferred embodiment in the order of steps;

FIG. 23 is a plan view showing the structure of a semiconductor device according to a second preferred embodiment of the invention;

FIG. 24 is a sectional view showing the structure of the semiconductor device according to the second preferred embodiment; and

FIGS. 25 through 30 are sectional views showing a method of manufacturing the semiconductor device according to the second preferred embodiment in the order of steps.

### DESCRIPTION OF THE PREFERRED EMBODIMENTS

### First Preferred Embodiment

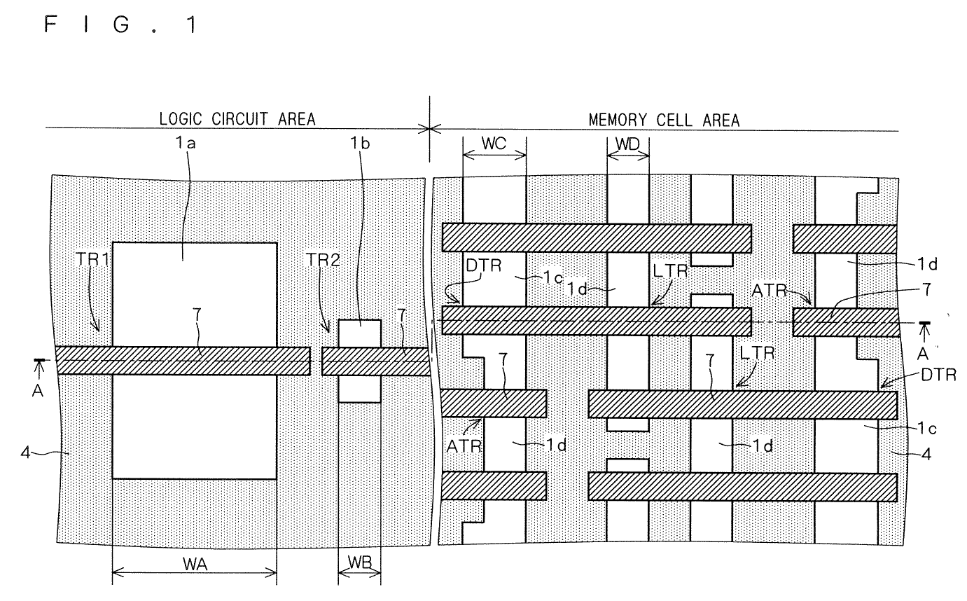

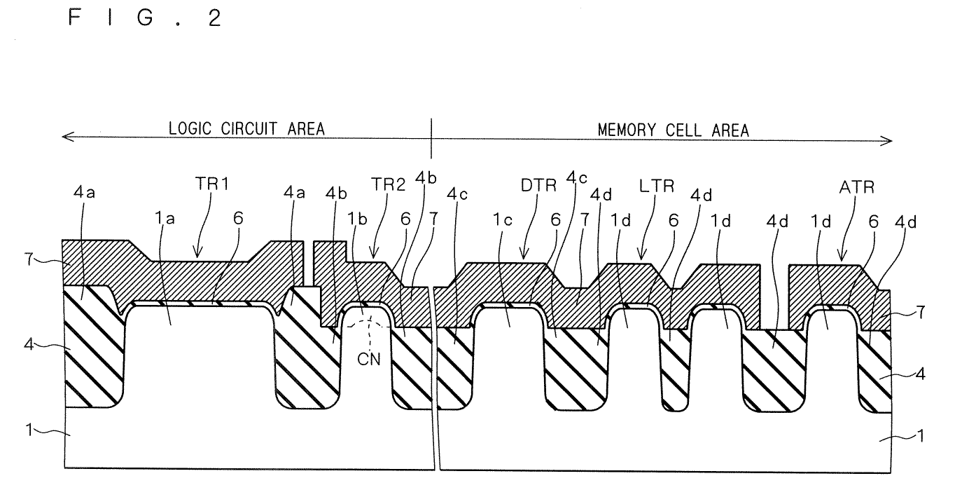

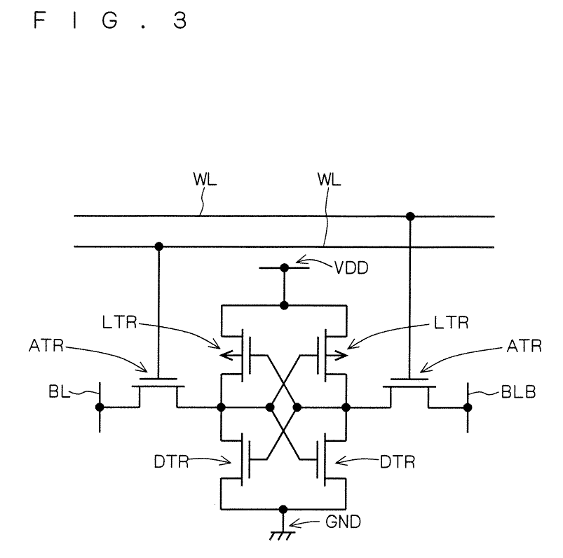

FIG. 1 is a plan view showing the structure of a semiconductor device according to a first preferred embodiment of the present invention, and FIG. 2 is a sectional view taken along the line A-A in FIG. 1. FIG. 3 is a circuit diagram of a memory cell provided in the semiconductor device according to the present embodiment.

The semiconductor device according to the present embodiment has a logic circuit area in which a logic circuit is formed and a memory cell area in which a plurality of memory cells are formed. For example, the semiconductor device has a logic circuit for performing data processing on image data or communication data and eSRAM (embedded SRAM). In the memory cell area, a plurality of memory cells in eSRAM, for example, are arranged in an array. In the logic circuit area, a peripheral circuit including column and row decoders for driving the plurality of memory cells and a logic circuit other than the peripheral circuit for processing image data or communication data are provided.

First, with reference to FIG. 3, the circuit diagram of a memory cell formed in the memory cell area according to the present embodiment is described. As shown in FIG. 3, the memory cell according to the present embodiment has two groups of a driver transistor DTR, a load transistor LTR and an access transistor ATR. The driver transistor DTR and access transistor ATR are NMOS transistors, and the load transistor LTR is a PMOS transistor.

In each of the two groups, the access transistor ATR has its gate connected to a word line WL. The drain of the driver transistor DTR, the drain of the load transistor LTR and the source of the access transistor ATR are connected to one another. The junction of the drain of the driver transistor DTR, the drain of the load transistor LTR and the source of the access transistor ATR of one of the two groups is connected to the gate of the load transistor LTR and the gate of the driver transistor DTR of the other group.

Further, in each of the two groups, a positive supply voltage VDD is applied to the source of the load transistor LTR, and a ground voltage GND is applied to the source of the driver transistor DTR. The access transistors ATR of the two groups have their drains connected to bit lines BL and BLB, respectively.

Now, with reference to FIGS. 1 and 2, the structure of the semiconductor device according to the present embodiment is described. As shown in FIGS. 1 and 2, the semiconductor device according to the present embodiment includes an isolation insulation film 4 formed in an upper surface of a semiconductor substrate 1 made of, e.g., Si. The isolation insulation film 4 is made of, e.g., silicon oxide, and defines active regions 1a and 1b in the semiconductor substrate 1 within the logic circuit area and active regions 1c and 1d in the semiconductor substrate 1 within the memory cell area. MOS transistors TR1 and TR2 are formed on the active regions 1a and 1b, respectively. The driver transistor DTR is formed on the active region 1c, and the load transistor LTR and access transistor ATR are formed on the active region 1d. The active region 1b is defined in a region of the logic circuit area adjacent to the memory cell area.

As viewed from above, the active region la has width WA greater than width WB of the active region 1b, width WC of the active region 1c and width WD of the active region 1d, as shown in FIG. 1. The width WB of the active region 1b is equal to the width WD of the active region 1d, and is smaller than the width WC of the active region 1c. Accordingly, the width WD is smaller than the width WC.

Herein, the width WA indicates the gate width of the MOS transistor TR1, which is a length of the active region la along the gate width of the MOS transistor TR1. Likewise, the width WB indicates the gate width of the MOS transistor TR2, which is a length of the active region 1b along the gate width of the MOS transistor TR2. The width WC indicates the gate width of the driver transistor DTR, which is a length of the active region 1c along the gate width of the driver transistor DTR. The width WD indicates the gate width of the access transistor ATR or load transistor LTR, which is a length of the active region 1d along the gate width of the access transistor ATR or load transistor LTR.

From the foregoing, the MOS transistor TR1 is greater than the MOS transistor TR2, driver transistor DTR, load transistor LTR and access transistor ATR in gate width. The MOS transistor TR2 is equal to the load transistor LTR and access transistor ATR in gate width, and smaller than the driver transistor DTR in gate width. Therefore, the MOS transistor TR1 is greater than the MOS transistor TR2, driver transistor DTR, load transistor LTR and access transistor ATR in current drive capability, and the MOS transistor TR2 is equal to the load transistor LTR and access transistor ATR in current drive capability, and smaller than the driver transistor DTR in current drive capability.

In the present embodiment, the widths WB, WC and WD of the active regions 1b, 1c and 1d are set not greater than 50 nm, and the width WA is set greater than 50 nm.

A gate insulation film 6 and a gate electrode 7 for the MOS transistors are stacked in this order on the active regions 1a to 1d. More specifically, the gate electrode 7 for the MOS transistor TR1 is formed on the active region la with the gate insulation film 6 interposed therebetween, and the gate electrode 7 for the MOS transistor TR2 is formed on the active region 1b with the gate insulation film 6 interposed therebetween. The gate electrode 7 for the driver transistor DTR is formed on the active region 1c with the gate insulation film 6 interposed therebetween, and the gate electrode 7 for the load transistor LTR or access transistor ATR is formed on the active region 1d with the gate insulation film 6 interposed therebetween. The gate insulation film 6 is made of, e.g., silicon oxide, and the gate electrode 7 is made of, e.g., polysilicon.

In the isolation insulation film 4 according to the present embodiment, as shown in FIG. 2, a peripheral portion 4b provided around the active region 1b, a peripheral portion 4c provided around the active region 1c and a peripheral portion 4d provided around the active region 1d have their upper surfaces positioned below the upper surface of a peripheral portion 4a provided around the active region 1a having the greatest width. The upper surface and side surfaces of part of the active region 1b facing each other along the gate width of the MOS transistor TR2 project upward from the upper surface of the peripheral portion 4b. The upper surface and side surfaces of part of the active region 1c facing each other along the gate width of the driver transistor DTR project upward from the upper surface of the peripheral portion 4c. The upper surface and side surfaces of part of the active region 1d facing each other along the gate width of the load transistor LTR or access transistor ATR project upward from the upper surface of the peripheral portion 4d.

In the present embodiment, the gate electrode 7 is formed on the upper surface and side surfaces of part of the active region 1b projecting upward from the upper surface of the peripheral portion 4b, the upper surface and side surfaces of part of the active region 1c projecting upward from the upper surface of the peripheral portion 4c, and the upper surface and side surfaces of part of the active region 1d projecting upward from the upper surface of the peripheral portion 4d, with the gate insulation film 6 interposed between the gate electrode 7 and these upper and side surfaces.

As described, the gate electrode 7 is formed to cover the upper surface and part of side surfaces facing each other along the gate width in the active region 1b on which the MOS transistor TR2 is formed. The gate structure of the MOS transistor TR2 therefore serves as the tri-gate structure. Accordingly, when applying a predetermined voltage to the gate electrode 7, a channel region CN extends from the upper surface and side surfaces of the active region 1b facing each other along the gate width to be spread over the whole area of the part of the active region 1b projecting from the isolation insulation film 4, as shown in FIG. 2. In this manner, according to the present embodiment, the channel region CN formed in the active region 1b can be controlled by a gate voltage from three directions. This ensures turn-on and turn-off of the MOS transistor TR2, which increases the difference between on-state current and off-state current, so that improved turn-on and turn-off characteristics are achieved.

Likewise, each of the driver transistor DTR, load transistor LTR and access transistor ATR has the tri-gate structure, and is capable of controlling the channel region by a gate voltage from multiple directions, so that the turn-on and turn-off characteristics of these transistors are improved.

The gate insulation film 6 may be formed thicker on the upper surface of the active region 1b than on the other portion, or a channel implantation dose into the active region 1b in the vicinity of the upper surface may be increased, to thereby make the conductivity type in the vicinity of the upper surface less likely to be reversed. Accordingly, when applying a predetermined voltage to the gate electrode 7, the channel region extends only from the side surfaces facing each other along the gate width in the active region 1b, so that the MOS transistor TR2 can have the double-gate structure that can control the channel region by a gate voltage from two directions. The same can be said about the driver transistor DTR, access transistor ATR and load transistor LTR.

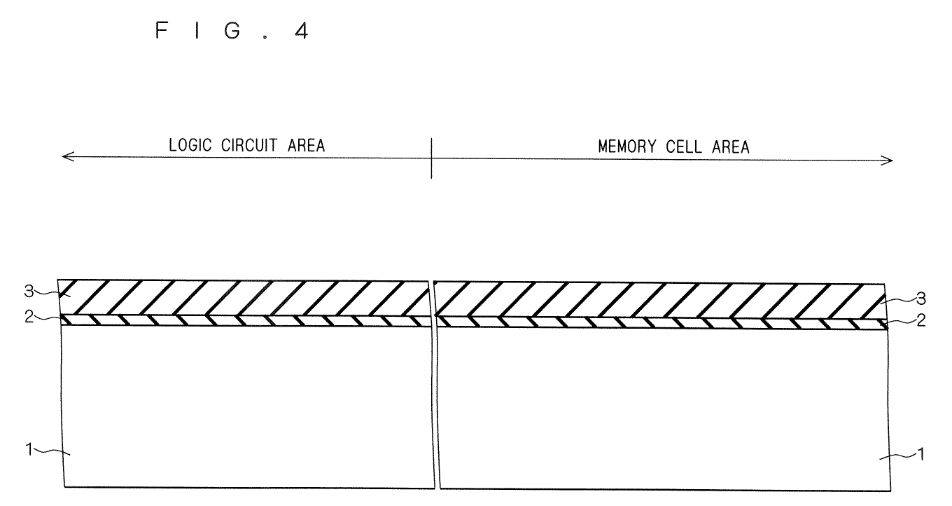

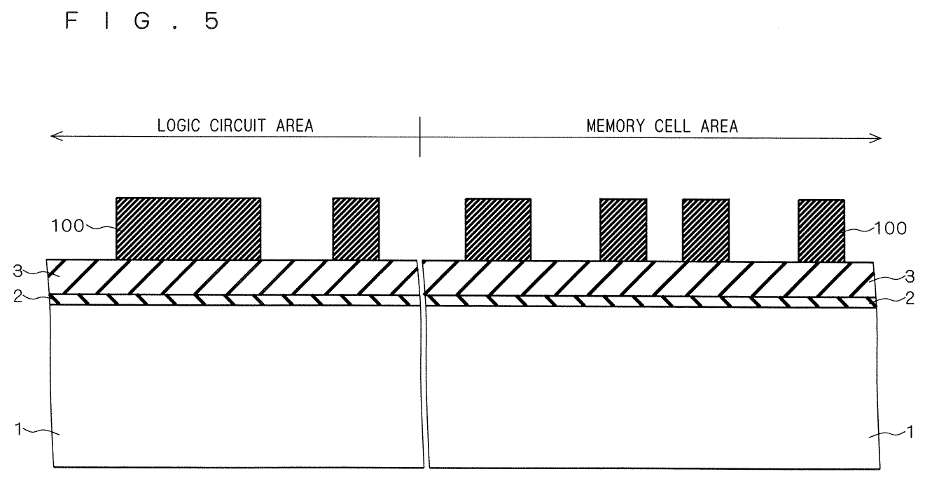

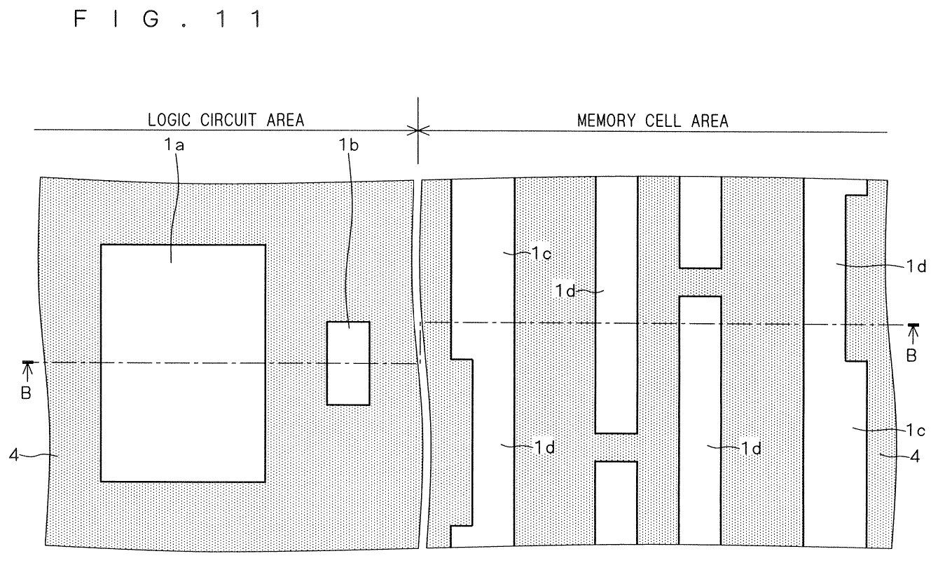

Next, a method of manufacturing the semiconductor device according to the present embodiment shown in FIGS. 1 and 2 is described. FIGS. 4 through 10, 12 and 13 are sectional views showing the method of manufacturing the semiconductor device according to the present embodiment in the order of steps, and FIG. 11 is a plan view showing the method. As shown in FIG. 4, a silicon oxide 2 and a silicon nitride 3 are first deposited in this order on the semiconductor substrate 1. Then, as shown in FIG. 5, a photoresist 100 having a predetermined resist pattern is formed on the silicon nitride 3.

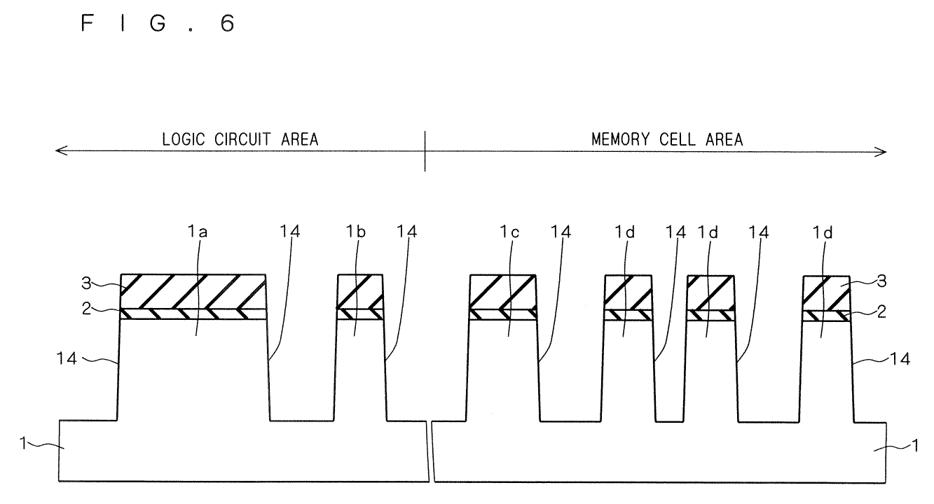

Subsequently, the silicon nitride 3, silicon oxide 2 and semiconductor substrate 1 are sequentially subjected to dry etching using the photoresist 100 as a mask, and the photoresist 100 is thereafter removed. Trenches 14 are thereby formed in the upper surface of the semiconductor substrate 1, as shown in FIG. 6. The trenches 14 respectively define the active regions 1a and 1b in the semiconductor substrate 1 within the logic circuit area and active regions 1c and 1d in the semiconductor substrate 1 within the memory cell area.

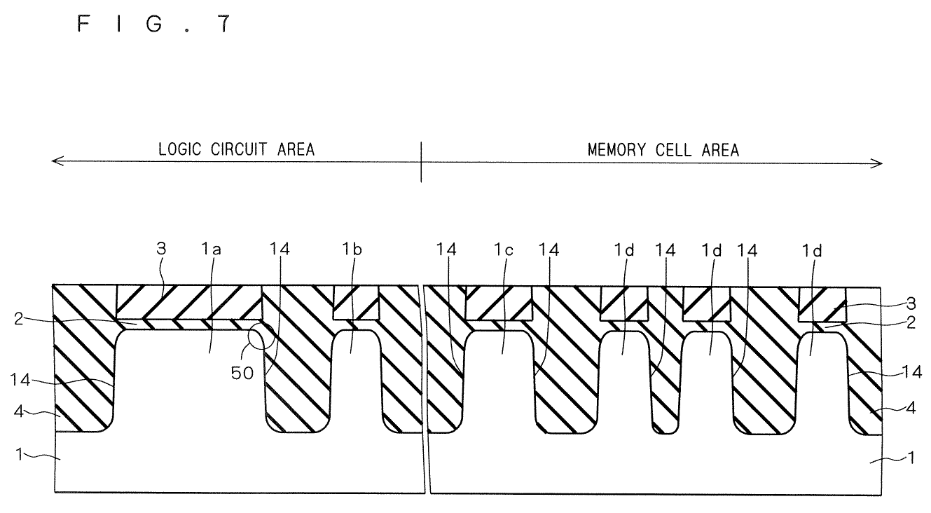

Next, a silicon oxide is formed on the entire surface to fill the trenches 14, and the surface of the silicon oxide is planarized by CMP method using the silicon nitride 3 as a stopper. The isolation insulation film 4 made of silicon oxide is thereby formed in about 200 to 400 nm depth to fill the trenches 14, as shown in FIG. 7. At this point of time, the MOS transistor TR1 and other transistors are yet to be formed, and therefore, in this step, the isolation insulation film 4 is formed such that the length of the active region 1c in a direction in which the gate width of the driver transistor DTR is to extend, the length of the active region 1d in a direction in which the gate width of the access transistor ATR or load transistor LTR is to extend, and the length of the active region 1b in a direction in which the gate width of the MOS transistor TR2 is to extend are smaller than the length of the active region 1a in a direction in which the gate width of the MOS transistor TR1 is to extend, and such that the length of the active region 1b is not greater than the lengths of the active regions 1c and 1d.

In the present embodiment, inner walls of part of the semiconductor substrate 1 exposed by the trenches 14 are subjected to thermal oxidation prior to filling the trenches 14 with the silicon oxide to be the isolation insulation film 4. Accordingly, in each of the active regions 1a to 1d, a corner 50 formed by the upper surface and a side surface connected thereto is rounded as shown in FIG. 7, which can relieve electric field concentration to the corner 50, so that the electric field generated in the active regions 1a to 1d can be made uniform. Instead of thermally oxidizing the inner walls of the semiconductor substrate 1, the semiconductor substrate 1 may be etched while rounding the corner 50 in dry etching for forming the trenches 14.

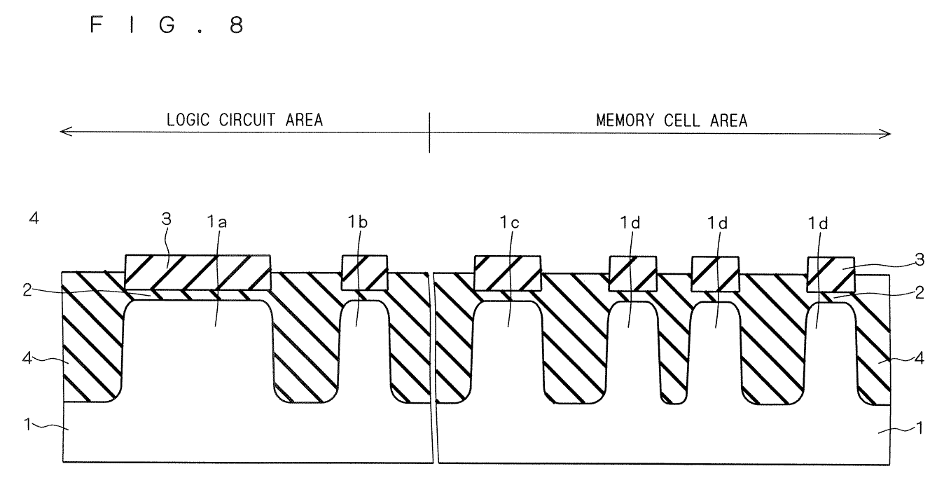

Next, as shown in FIG. 8, the upper portion of the isolation insulation film 4 is selectively removed by wet etching to make the silicon nitride 3 partly project from the isolation insulation film 4. At this time, the upper surface of the isolation insulation film 4 is made not to be positioned below the upper surfaces of the active regions 1a to 1d. For instance, the upper surface of the isolation insulation film 4 is positioned about 40 nm above the upper surfaces of the active regions 1a to 1d.

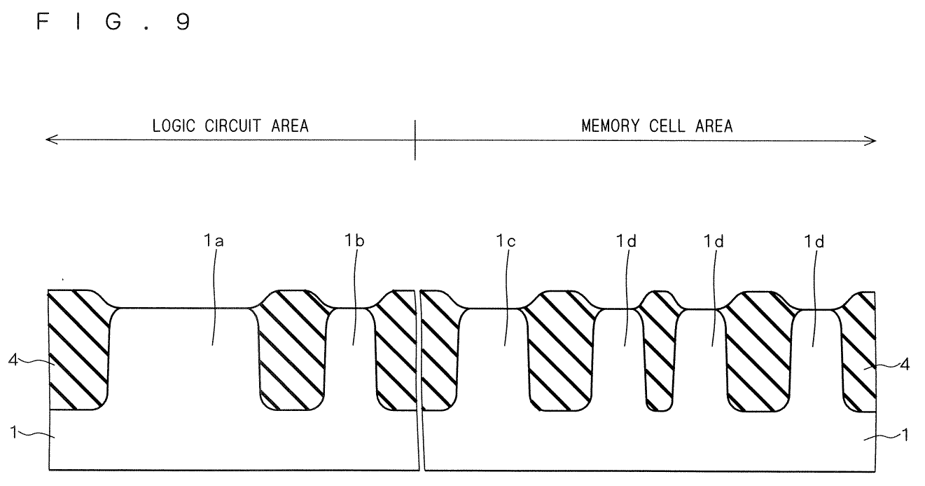

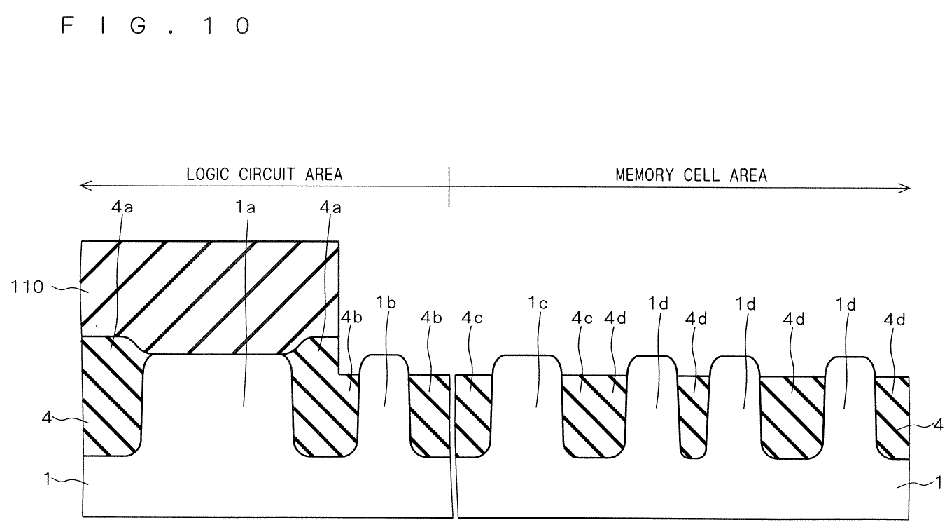

Next, as shown in FIG. 9, the silicon nitride 3 and silicon oxide 2 are sequentially removed by wet etching. Then, as shown in FIG. 10, a photoresist 110 is formed on the semiconductor substrate 1 to cover the active region la in the logic circuit area and the peripheral portion 4a provided around the active region la in the isolation insulation film 4, and the exposed part of the isolation insulation film 4 is selectively wet-etched using the photoresist 110 as a mask. Accordingly, the peripheral portion 4b provided around the active region 1b in the isolation insulation film 4 and the whole part of the isolation insulation film 4 in the memory cell area are removed, so that the upper surface of the isolation insulation film 4 is etched down by about 50 to 150 nm. As a result, in the isolation insulation film 4, the upper surface of the peripheral portion 4a is not etched down, whereas the upper surface of the peripheral portion 4b is etched down below the upper surface of the active region 1b. At the same time, in the isolation insulation film 4, the upper surface of the peripheral portion 4c provided around the active region 1c is etched down below the upper surface of the active region 1c, and the upper surface of the peripheral portion 4d provided around the active region id is etched down below the upper surface of the active region 1d.

FIG. 11 is a plan view of the structure shown in FIG. 10. In FIG. 11, illustration of the photoresist 110 shown in FIG. 10 is omitted. The structure shown in FIG. 10 is obtained by forming the photoresist 110 in the sectional structure taken along the line B-B in FIG. 11.

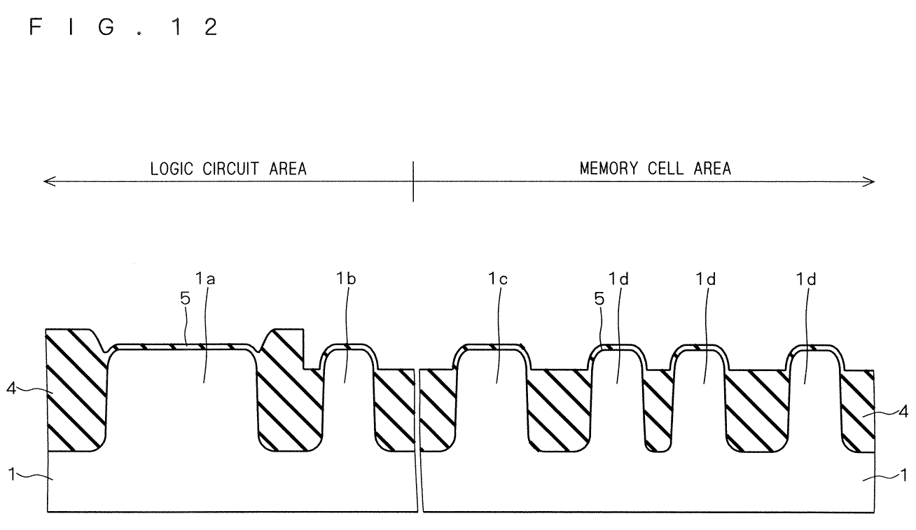

Next, as shown in FIG. 12, a silicon oxide 5 serving as a screen in ion implantation is formed on the upper surfaces of the active regions 1a to 1d. P- or n-type impurities are then ion implanted into the semiconductor substrate 1 through the silicon oxide 5 to form a well region (not shown) in the upper surface of the semiconductor substrate 1. Subsequently, p- or n-type impurities are ion implanted into the semiconductor substrate 1 to determine threshold voltages of the MOS transistors TR1, TR2, driver transistor DTR and the like. The silicon oxide 5 is thereafter removed.

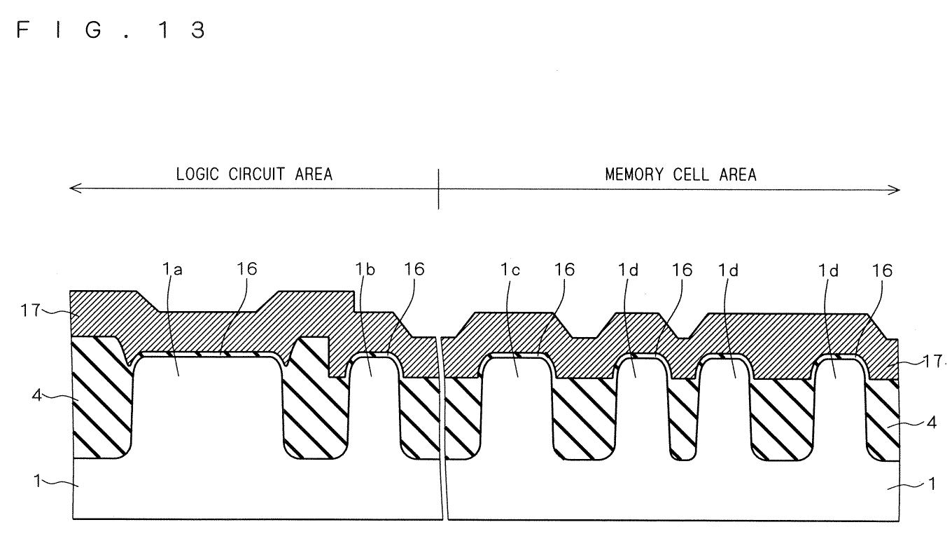

Next, as shown in FIG. 13, a silicon oxide 16 to be a gate insulation film for the MOS transistor TR1 and the like is formed on the active regions 1a to 1d, and then, a polysilicon film 17 to be the gate electrode 7 for the MOS transistor TR1 and the like is formed on the entire surface.

Next, the polysilicon film 17 and silicon oxide 16 are patterned to form the gate electrode 7 made of the polysilicon film 17 and the gate insulation film 6 made of the silicon oxide 16. Accordingly, in the logic circuit area, the gate electrode 7 is formed on the active region 1a with the gate insulation film 6 interposed therebetween, and on the upper surface and side surfaces of part of the active region 1b facing each other along the gate width that projects upward from the upper surface of the isolation insulation film 4 with the gate insulation film 6 interposed therebetween. In the memory cell area, the gate electrode 7 is formed on the upper surface and side surfaces of part of the active region 1c facing each other along the gate width that projects upward from the upper surface of the isolation insulation film 4, with the gate insulation film 6 interposed therebetween, and the gate electrode 7 is formed on the upper surface of the active region 1d and part of its side surfaces facing each other along the gate width that projects upward from the upper surface of the isolation insulation film 4 with the gate insulation film 6 interposed therebetween.

Next, sidewalls (not shown) are formed on side surfaces of the gate insulation film 6 and gate electrode 7, and source/drain regions (not shown) for the MOS transistor TR1 and the like are formed. At this time, the upper surface of the isolation insulation film 4 in the memory cell area is positioned about 30 to 130 nm below the upper surfaces of the active regions 1c and 1d. Likewise, the upper surface of the peripheral portion 4b in the logic circuit area is positioned about 30 to 130 nm below the upper surface of the active region 1b. Thereafter, an interlayer insulation film, a contact plug and interconnect wires, not shown, are formed. The driver transistor DTR, access transistor ATR and load transistor LTR are thereby electrically connected to one another, so that the semiconductor device according to the present embodiment is completed.

As described, in the logic circuit area according to the present embodiment, the structure applied to the active regions 1c and 1d formed in the memory cell area is also applied to the active region 1b having a width not greater than the active regions 1c and 1d, so that the MOS transistor TR2 formed on the active region 1b has the tri- or double-gate structure. That is, the tri- or double-gate structure is obtained by forming the gate electrode 7 on the upper surface and side surfaces of part of the active region 1b facing each other along the gate width that projects upward from the upper surface of the isolation insulation film 4, with the gate insulation film 6 interposed therebetween.

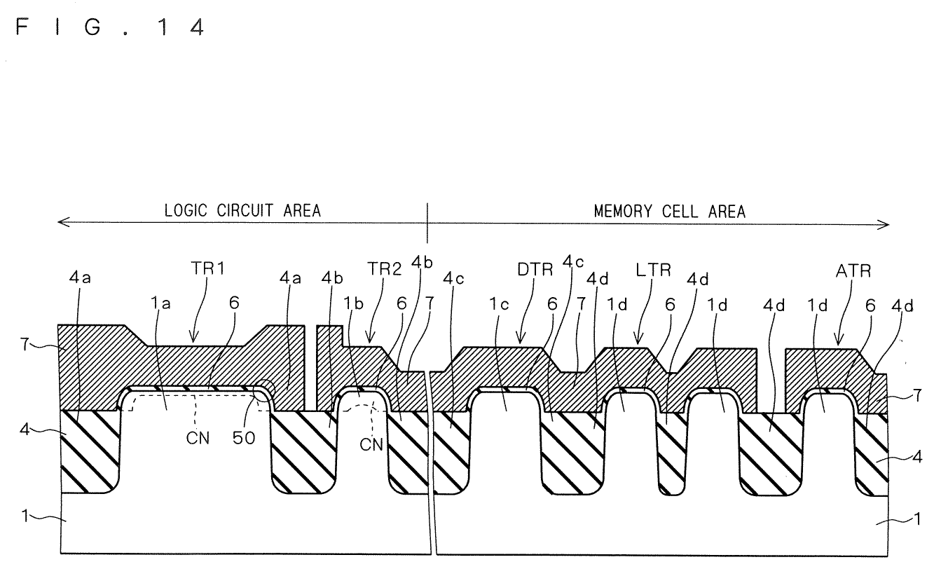

On the other hand, if the structure applied to the active regions 1c and 1d in the memory cell area is applied to the active region 1a in the logic circuit area to configure the MOS transistor TR1 to have the double- or tri-gate structure, the channel region CN is only formed in the vicinity of the upper and side surfaces of the active region 1a as shown in FIG. 14 because the width WA of the active region 1a is relatively great. It is therefore difficult to form the channel region CN in the whole area of the part of the active region 1a projecting upward from the upper surface of the isolation insulation film 4. Reducing the channel doping amount to control impurity concentrations so that the channel region CN is easily formed, the potential in the vicinity of the corner 50 formed by the upper and side surface connected thereto in the active region 1a tends to decrease more than necessary, which causes a phenomenon that the channel is difficult to be turned off at the corner 50. As a result, leakage current flows into the active region 1a through the corner 50 even when applying a turn-off voltage to the gate electrode 7, which increases off-state leakage current. Therefore, it is not desirable to configure the logic circuit that requires such large active region 1a to have the double- or tri-gate structure.

Further, a highly-reliable thick gate insulation film needs to be formed for a MOS transistor that is used for an interface circuit in the logic circuit, that is, a MOS transistor that always continues to drive at high drive voltages. If forming such MOS transistor in the active region la as the MOS transistor TR1 to configure the MOS transistor TR1 to have the double- or tri-gate structure, the gate insulation film 6 for the MOS transistor TR1 would be formed on sidewalls of a trench that is partly filled with an isolation insulation film. In comparison with a (100)-oriented surface for use as the upper surface of a silicon substrate, a silicon oxide formed on a surface of another orientation is inherently of poor quality, and besides, the sidewalls of the trench are cut down by etching, and therefore suffer great damage. For these reasons, the sidewalls of the trench are not desirable for forming thereon the gate insulation film 6 for the MOS transistor TR1. Therefore, when forming a MOS transistor for use in an interface circuit on the active region 1a, it is not preferable to configure the MOS transistor to have the double- or tri-gate structure.

Furthermore, a plurality of memory cells are generally configured with a repetitive layout pattern, and therefore, the degree of difficulty of a lithography process for forming the memory cells is low, and a plurality of active regions on which the memory cells are formed can be arranged densely. The widths WC and WD of the active regions 1c and 1d in the memory cell area can therefore be formed relatively small. Since the layout pattern of a region of the logic circuit area adjacent to the memory cell area is also usually configured with a repetitive pattern, the degree of difficulty of a lithography process for forming that region is low, and a plurality of active regions formed in that region can be arranged densely. Accordingly, the width WB of the active region 1b formed in a region of the logic circuit area adjacent to the memory cell area can be made not greater than the widths WC and WD of the active regions 1c and 1d in the memory cell area. For instance, the width WB of the active region 1b can be set not greater than 50 nm, as described in the present embodiment.

As described, in the logic circuit area according to the present embodiment, the active region 1b having the sufficiently small width WB is configured to have the same structure as the memory cell area so as to achieve the double- or tri-gate structure. This ensures the channel region CN to be formed in the whole area of the part of the active region projecting upward from the upper surface of the isolation insulation film 4, as shown in FIG. 2. This ensures improved turn-on and turn-off characteristics of the MOS transistor TR2 formed on the active region 1b, and reduces the off-state leakage current in the whole device.

Further, the double- or tri-gate structure is not employed for a gate structure that is formed in a relatively large active region in the logic circuit area such as the active region 1a. This can prevent a transistor whose channel region CN is difficult to be formed and having a high threshold voltage or a transistor having a high off-state leakage current from being formed in such active region.

Furthermore, when forming a MOS transistor for use in an interface circuit in the active region 1a, the double- or tri-gate structure is not employed for the gate structure of the MOS transistor. This allows generation of a good-quality and highly-reliable gate insulation film.

According to the present embodiment, the widths WC and WD of the active regions 1c and 1d in the memory cell area and the width WB of the active region 1b in the logic circuit area are set not greater than 50 nm, which allows the double- or tri-gate structure to exert its effects sufficiently. From a manufacturability standpoint, the widths WB and WD of the active regions 1b and 1d are preferably set at 20 to 40 nm, and the width WC of the active region 1c is preferably set at 30 to 50 nm.

According to the method of manufacturing the semiconductor device of the present embodiment, the semiconductor substrate 1 is subjected to etching using the photoresist 100 having a predetermined resist pattern as a mask to form the trenches 14; however, when the resist pattern formed on the photoresist 100 cannot be formed sufficiently thin due to constraints in performance of a photolithography apparatus to be used, the silicon nitride 3 may sequentially be subjected to anisotropic etching and isotropic etching, and the semiconductor substrate 1 may be etched using the silicon nitride 3 having undergone isotropic etching as a mask to form the trenches 14. This method is described in detail below.

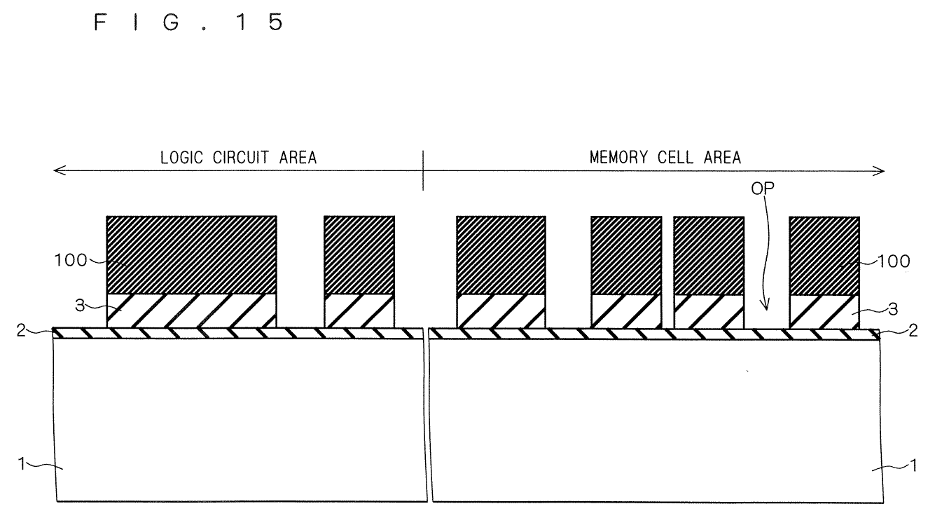

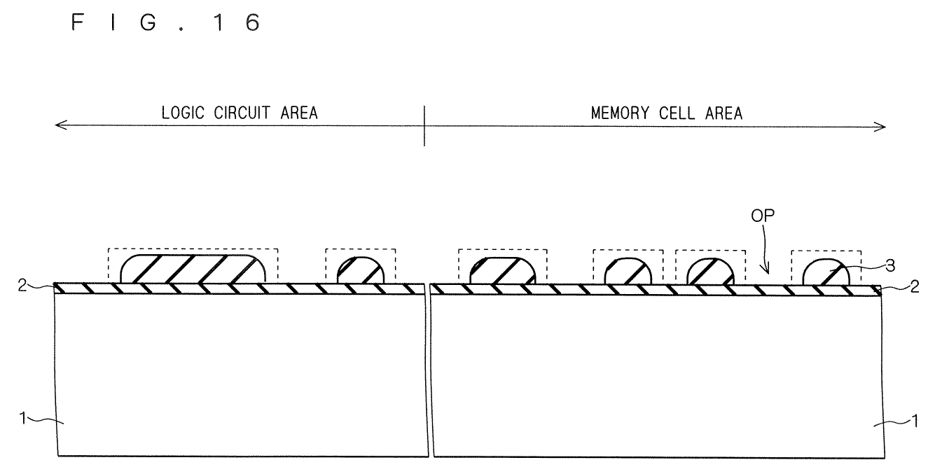

FIGS. 15 and 16 are sectional views showing a modified method of manufacturing a semiconductor device according to the present embodiment in the order of steps. First, the silicon oxide 2 and silicon nitride 3 are deposited in this order on the semiconductor substrate 1 to obtain the structure shown in FIG. 4. Then, as shown in FIG. 15, the photoresist 100 having a predetermined resist pattern is formed on the silicon nitride 3. Using the photoresist 100 as a mask, an exposed part of the silicon nitride 3 is subjected to anisotropic dry etching at higher etch rates in the thickness direction of the semiconductor substrate 1 than in a direction perpendicular to the thickness direction, and the photoresist 100 is removed. Openings OP that partly expose the silicon oxide 2 are thereby formed in the silicon nitride 3.

Since the use of an inexpensive photolithography apparatus is assumed in this modification, the resist pattern cannot be formed very thin. The resist pattern of the photoresist 100 shown in FIG. 15 is therefore wider than that of the resist pattern shown in FIG. 5. Accordingly, if the semiconductor substrate 1 in this state is etched using the silicon nitride 3 as a mask to form the trenches 14, the widths of the active regions 1a to 1d defined by the trenches 14 would be greater than designed values. Therefore, as shown in FIG. 16, the silicon nitride 3 is subjected to isotropic wet etching using, e.g., phosphorus to selectively and partially remove the silicon nitride 3. The openings OP formed in the silicon nitride 3 by anisotropic dry etching are thereby extended, which increases an exposed part of the silicon oxide 2 in area.

Next, using the silicon nitride 3 having undergone isotropic wet etching as a mask, the exposed part of the silicon oxide 2 and underlying semiconductor substrate 1 are subjected to dry etching. The trenches 14 of the same shape as shown in FIG. 6 are thereby formed in the semiconductor substrate 1, and the active regions la to 1d are defined by the trenches 14.

As described, adopting anisotropic etching and isotropic etching in combination when forming predetermined openings OP in the silicon nitride 3 serving as a mask for forming the trenches 14 allows the active regions 1b to 1d to be formed thin even when the line width of the resist pattern cannot be formed very thin due to constraints in performance of the photolithography apparatus.

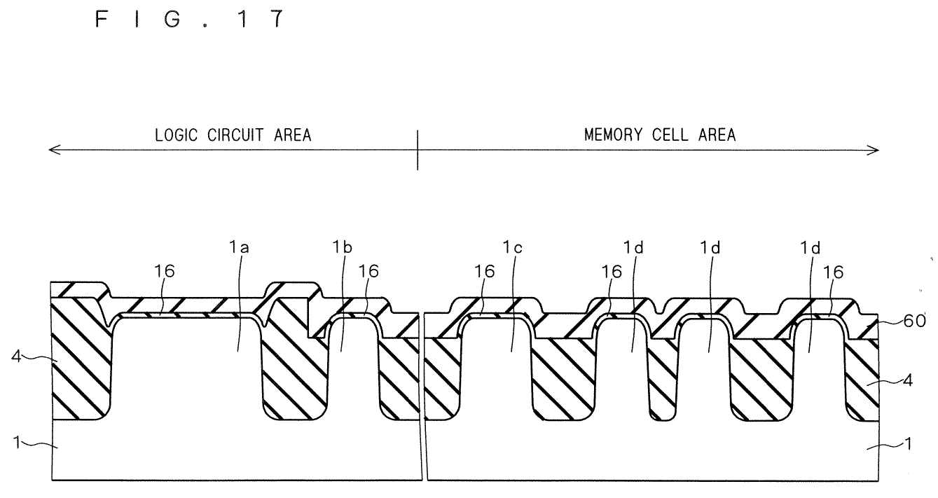

Further, as already described, the gate insulation film 6 is formed thicker on the upper surfaces of the active regions 1b to 1d than on their sidewalls, so that the transistors such as the MOS transistor TR2 and driver transistor DTR can be configured to have the double-gate structure. A method of manufacturing a semiconductor device in this case is described below with reference to FIGS. 17 to 19.

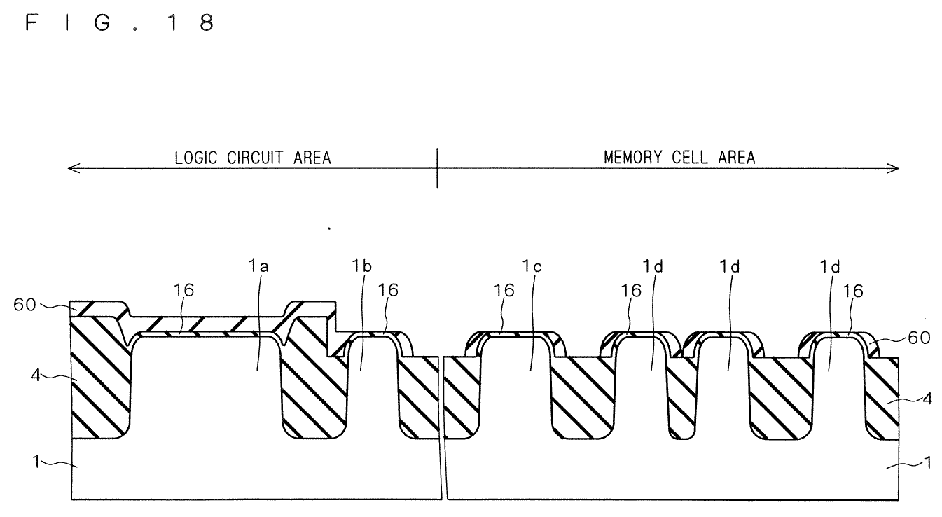

First, the silicon oxide 16 to be the gate insulation film is formed by the aforementioned method. Next, as shown in FIG. 17, a silicon nitride 60 is formed on the entire surface. A photoresist (not shown) is then formed to cover part of the silicon nitride 60 that is positioned on the active region 1a, and an exposed part of the silicon nitride 60 is subjected to anisotropic dry etching at higher etch rates in the thickness direction of the semiconductor substrate 1 than in a direction perpendicular to the thickness direction. Accordingly, as shown in FIG. 18, sidewalls made of the silicon nitride 60 are formed on side surfaces of parts of the active regions 1b to 1d that are positioned above the upper surface of the isolation insulation film 4, with the silicon oxide 16 interposed therebetween.

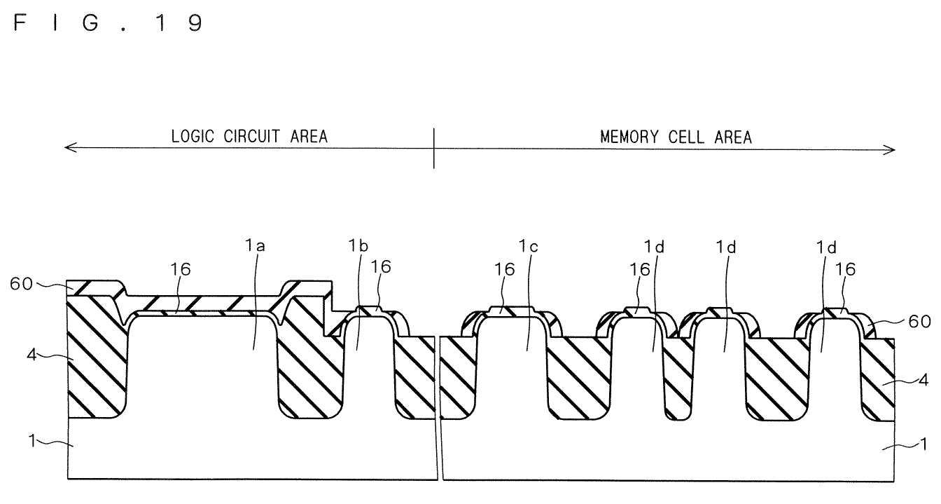

Next, the structure shown in FIG. 18 is subjected to thermal oxidization. The side surfaces of part of the active region 1b that is positioned above the upper surface of the isolation insulation film 4 are covered by the sidewalls made of the silicon nitride 60, and are therefore not oxidized, but the upper surface of the active region 1b is oxidized. Accordingly, as shown in FIG. 19, the silicon oxide 16 becomes thick only on the upper surface of the active region 1b. That is, the silicon oxide 16 is formed thicker on the upper surface than on the side surfaces of the active region 1b.

Likewise, the silicon oxide 16 is formed thicker on the upper surface than on the other portion of the active region 1c, and formed thicker on the upper surface than on the other portion of the active region 1c.

Thereafter, the silicon nitride 60 is removed by wet etching or the like, and the polysilicon film 17 to be the gate electrode 7 is formed similarly to the aforementioned method, and the polysilicon film 17 and silicon oxide 16 are patterned. Accordingly, the gate insulation film 6 on the active regions 1b to 1d is formed thicker on the upper surfaces of the active regions 1b to 1d than on their side surfaces, so that the transistors such as the MOS transistor TR2 and driver transistor DTR can be configured to have the double-gate structure.

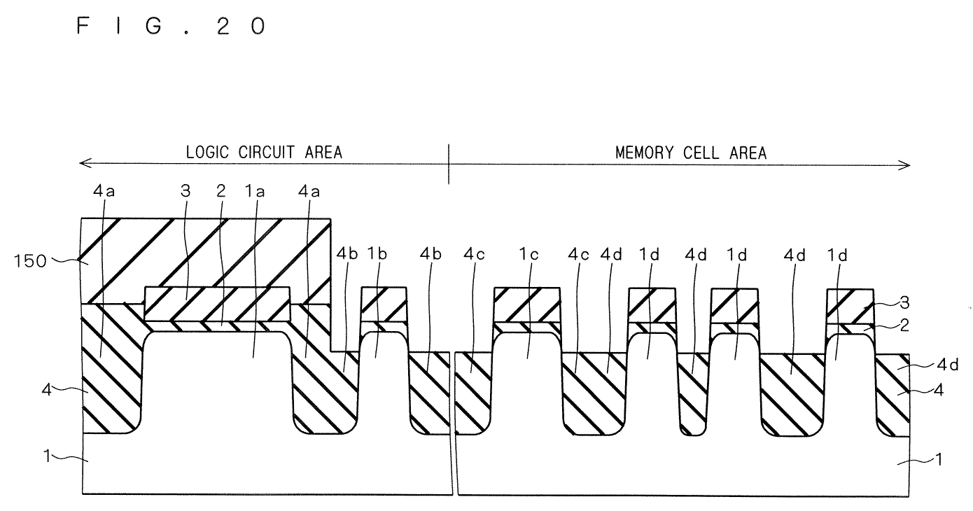

The double-gate structure can be achieved by a different method than that described with reference to FIGS. 17 to 19. First, the structure shown in FIG. 8 is prepared by the aforementioned method. Then, as shown in FIG. 20, a photoresist 150 is formed on the semiconductor substrate 1 to cover the active region la in the logic circuit area and the peripheral portion 4a of the isolation insulation film 4, and the exposed part of the isolation insulation film 4 is selectively wet etched using the photoresist 150 as a mask. The exposed part of the isolation insulation film 4 is thereby removed. Accordingly, the upper surface of the peripheral portion 4a is not etched down, whereas the upper surface of the peripheral portion 4b is etched down below the upper surface of the active region 1b. At the same time, in the memory cell area, the upper surface of the peripheral portion 4c is etched down below the upper surface of the active region 1c, and the upper surface of the peripheral portion 4d is etched down below the upper surface of the active region 1d. The photoresist 150 is thereafter removed.

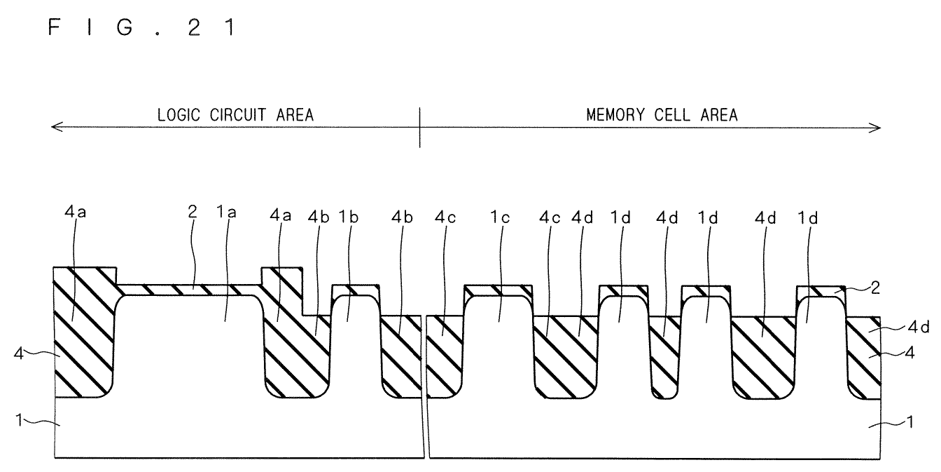

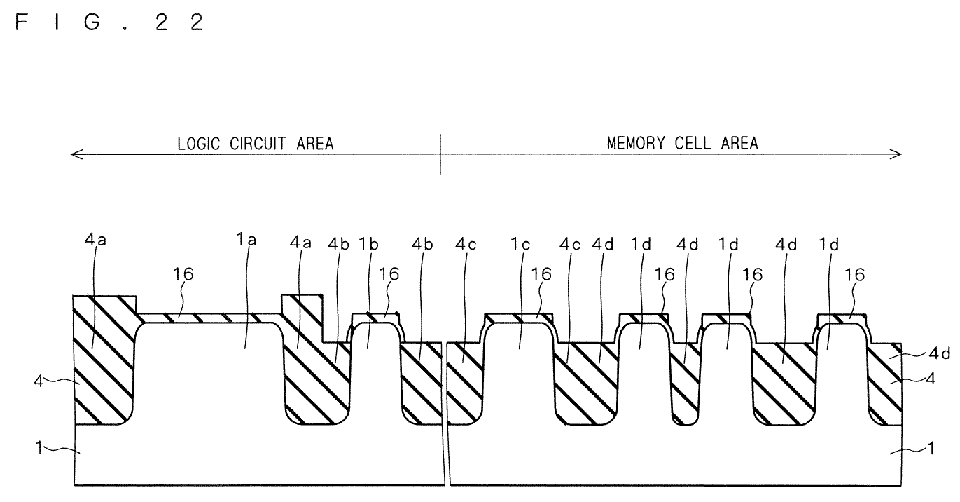

Next, as shown in FIG. 21, the silicon nitride 3 is removed. The structure shown in FIG. 21 is then subjected to thermal oxidization. The upper and side surfaces of part of the active regions 1b to 1d positioned above the upper surface of the isolation insulation film 4 are thermally oxidized, so that the silicon oxide 16 to be the gate insulation film 6 is formed on the active regions 1b to 1d, as shown in FIG. 22. Since the silicon oxide 2 has already been formed on the upper surfaces of the active regions 1b to 1d by this time, the silicon oxide 16 is thicker on the upper surfaces of the active regions 1b to 1d than on their side surfaces.

Next, a well region (not shown) is formed in the upper surface of the semiconductor substrate 1, and impurities are ion implanted into the semiconductor substrate 1 to determine threshold voltages of the transistors such as the MOS transistors TR1, TR2 and driver transistor DTR. Then, the polysilicon film 17 to be the gate electrode 7 is formed on the entire surface. The polysilicon film 17 and silicon oxide 16 are then patterned to form the gate electrode 7 and gate insulation film 6. At this time, the gate insulation film 6 on the active region 1b is formed thicker on the upper surface than on the other portion, and the MOS transistor TR2 can be configured to have the double-gate structure. Likewise, the driver transistor DTR, load transistor LTR and access transistor ATR can be configured to have the double-gate structure.

### Second Preferred Embodiment

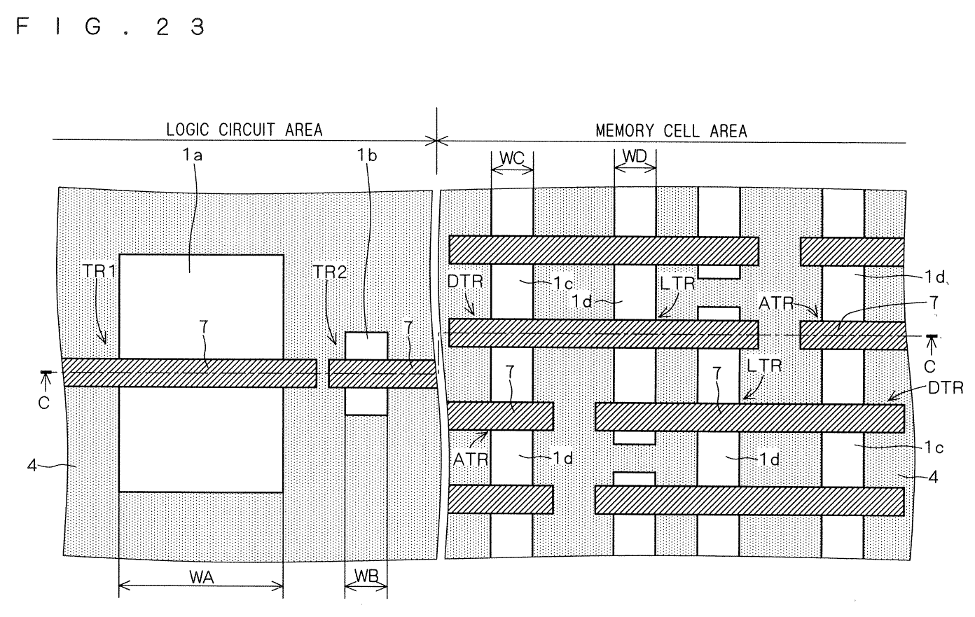

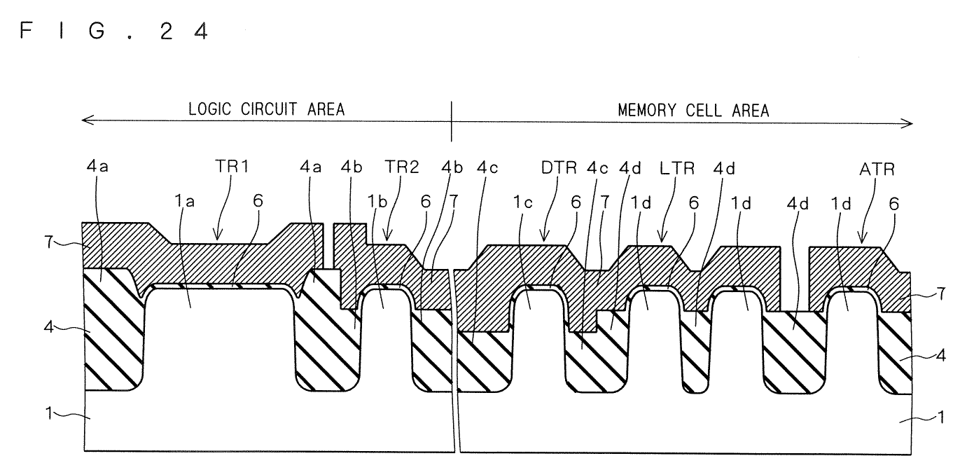

FIG. 23 is a plan view showing the structure of a semiconductor device according to a second preferred embodiment of the invention. FIG. 24 is a sectional view taken along the line C-C shown in FIG. 23. The semiconductor device according to the present embodiment differs from that of the first preferred embodiment in the width WC of the active region 1c as viewed from above and the height of the peripheral portion 4c in the isolation insulation film 4.

In the present embodiment, as shown in FIG. 23, the width WC of the active region 1c is equal to the width WD of the active region 1d as viewed from above. Accordingly, in the present embodiment, the width WB of the active region 1b, width WC of the active region 1c and width WD of the active region 1d are equal to one another, and smaller than the width WA of the active region 1a. The widths WB to WD of the active regions 1b to 1d are set not greater than 50 nm, and preferably at 20 to 50 nm from a manufacturability standpoint.

In the isolation insulation film 4 according to the present embodiment, the upper surface of the peripheral portion 4c is positioned below the upper surfaces of the peripheral portions 4b and 4d, as shown in FIG. 24. The rest of the structure is the same as that of the first preferred embodiment, and repeated explanation thereof is omitted here.

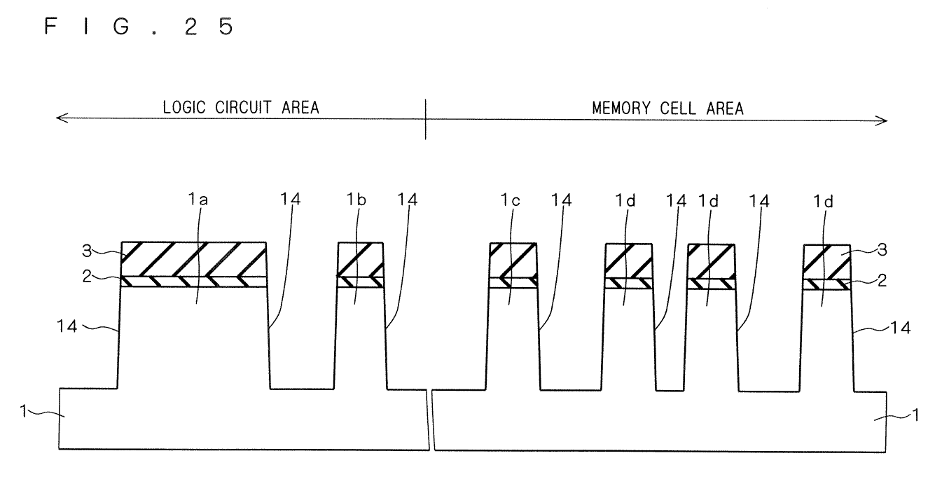

Next, a method of manufacturing the semiconductor device shown in FIGS. 23 and 24 is described. FIGS. 25 through 30 are sectional views showing the method of manufacturing the semiconductor device according to the present embodiment in the order of steps. First, the aforementioned structure shown in FIG. 5 is prepared by the method according to the first preferred embodiment. At this time, the plurality of openings formed in the photoresist 100 in the memory cell area are formed in equal width. Next, the silicon nitride 3, silicon oxide 2 and semiconductor substrate 1 are sequentially subjected to dry etching using the photoresist 100 as a mask. The photoresist 100 is thereafter removed. As shown in FIG. 25, the trenches 14 are thereby formed in the upper surface of the semiconductor substrate 1, and the trenches 14 define the active regions 1a and 1b in the semiconductor substrate 1 within the logic circuit area and the active regions 1c and 1d in the semiconductor substrate 1 within the memory cell area. At this time, the widths WB, WC and WD of the active regions 1b, 1c and 1d are equal to one another as viewed from above.

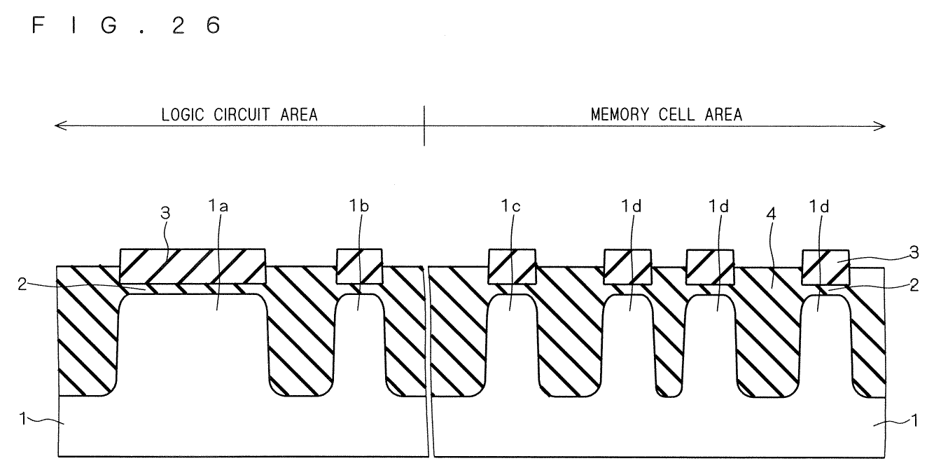

Next, a silicon oxide is formed on the entire surface to fill the trenches 14, and the silicon oxide is planarized by CMP using the silicon nitride 3 as a stopper to form the isolation insulation film 4 made of the silicon oxide in the trenches 14. Then, the upper part of the isolation insulation film 4 is selectively removed by wet etching. The silicon nitride 3 thereby projects from the isolation insulation film 4 as shown in FIG. 26.

Similarly to the first preferred embodiment, the inner walls of the semiconductor substrate 1 exposed by the trenches 14 may be thermally oxidized prior to filling the trenches 14 with the silicon oxide to be the isolation insulation film 4. Accordingly, in each of the active regions 1a to 1d, a corner formed by the upper surface and a side surface connected thereto is rounded, so that the electric field occurred in the active regions 1a to 1d can be made uniform. FIG. 26 shows the structure in which the comer is rounded in each of the active regions 1a to 1d.

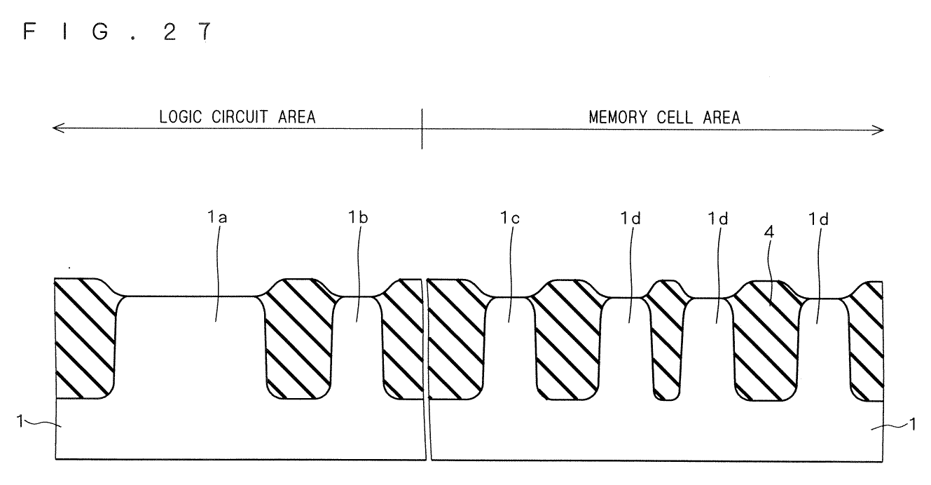

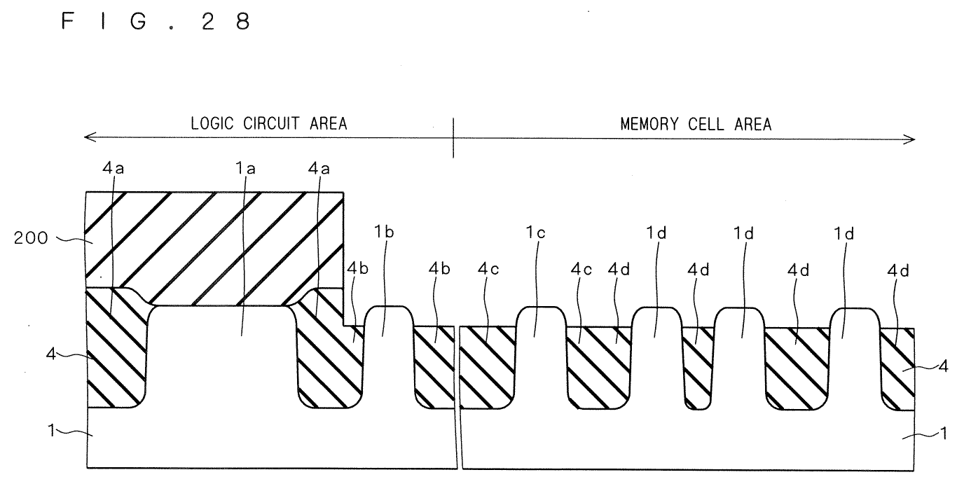

Next, as shown in FIG. 27, the silicon nitride 3 and silicon oxide 2 are sequentially removed by wet etching. Then, as shown in FIG. 28, a photoresist 200 is formed on the semiconductor substrate 1 to cover the active region 1a in the logic circuit area and the peripheral portion 4a of the isolation insulation film 4, and the exposed part of the isolation insulation film 4 is selectively wet etched using the photoresist 200 as a mask. The photoresist 200 is thereafter removed. The exposed part of the isolation insulation film 4 is thereby partly removed, and the upper surface of the isolation insulation film 4 is etched down by about 50 to 150 nm. As a result, in the isolation insulation film 4, the upper surface of the peripheral portion 4a is not etched down, whereas the upper surface of the peripheral portion 4b is etched down below the upper surface of the active region 1b. At the same time, the upper surface of the peripheral portion 4c is etched down below the upper surface of the active region 1c, and the upper surface of the peripheral portion 4d is etched down below the upper surface of the active region 1d.

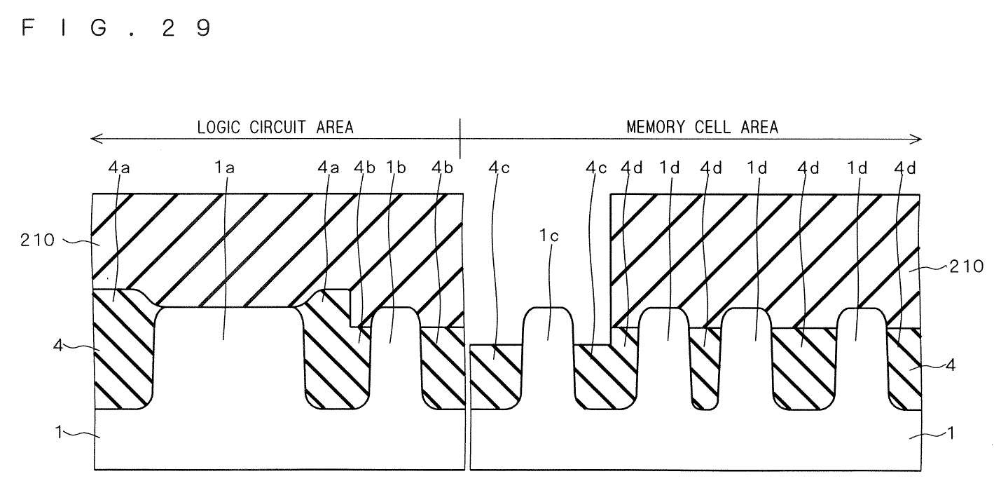

Next, as shown in FIG. 29, a photoresist 210 is formed to cover the whole area of the logic circuit area and the active region 1d and peripheral portion 4d in the memory cell area, and the exposed part of the isolation insulation film 4 is selectively wet etched using the photoresist 210 as a mask. Accordingly, only the peripheral portion 4c is removed, and the upper surface of the peripheral portion 4c is etched down by about 30 to 100 nm. As a result, in the isolation insulation film 4, the upper surfaces of the peripheral portions 4a, 4b and 4d are not etched down, whereas the upper surface of the peripheral portion 4c is etched down below the upper surfaces of the peripheral portions 4b and 4d. The photoresist 210 is thereafter removed.

Next, similarly to the first preferred embodiment, a silicon oxide to be used as a screen in ion implantation is formed on the upper surfaces of the active regions 1a to 1d, and impurities are ion implanted into the semiconductor substrate 1 through the silicon oxide to form a well region in the upper surface of the semiconductor substrate 1. Then, impurities are ion implanted into the semiconductor substrate 1 to determine threshold voltages of the transistors such as the MOS transistors TR1, TR2 and driver transistor DTR. The silicon oxide used as a screen is thereafter removed.

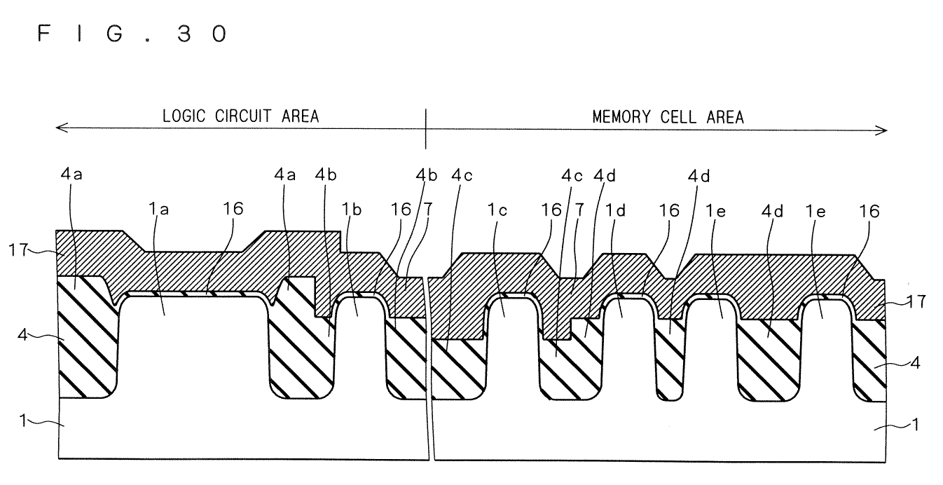

Next, as shown in FIG. 30, the silicon oxide 16 to be the gate insulation film 6 for the MOS transistor TR1 and the like is formed on the active regions 1a to 1d, and the polysilicon film 17 to be the gate electrode 7 for the MOS transistor TR1 and the like is formed on the entire surface. Then, the polysilicon film 17 and silicon oxide 16 are patterned to form the gate electrode 7 made of the polysilicon film 17 and the gate insulation film 6 made of the silicon oxide 16.

Thereafter, sidewalls (not shown) are formed on the side surfaces of the gate insulation film 6 and gate electrode 7, and a source/drain region (not shown) for the MOS transistor TR1 and the like are formed. Then, an interlayer insulation film, a contact plug and interconnect wires, not shown, are formed. The semiconductor device according to the present embodiment is thereby completed.

As described, in the isolation insulation film 4 according to the present embodiment, the upper surface of the peripheral portion 4c provided around the active region 1c is positioned below the upper surface of the peripheral portion 4d provided around the active region 1d, so that the part of the active region 1c positioned above the upper surface of the isolation insulation film 4 can be made greater in volume than the part of the active region 1d positioned above the upper surface of the isolation insulation film 4. The channel region formed in the active region 1c therefore has a greater volume than that in the active region 1d. Accordingly, even when setting the widths WC and WD of the active regions 1c and 1d equal to each other as described in the present embodiment, the driver transistor DTR can be made greater than the load transistor LTR and access transistor ATR in drive current capability. This allows a simple layout pattern in the memory cell area while forming a plurality of MOS transistors each having a different current drive capability, which ensures a sufficient process margin in a photolithography process. The semiconductor device can therefore be improved in performance.

Further, since the width WC of the active region 1c on which the driver transistor DTR is to be formed can be reduced while maintaining the current drive capability of the driver transistor DTR, memory cells can be reduced in size, which allows size reduction of the semiconductor device.

When the resist pattern on the photoresist 100 used in forming the trenches 14 cannot be made sufficiently thin due to constraints in performance of a photolithography apparatus to be used, the silicon nitride 3 may sequentially be subjected to anisotropic etching and isotropic etching similarly to the first preferred embodiment, and the semiconductor substrate 1 may be etched using the silicon nitride 3 having undergone isotropic etching as a mask to form the trenches 14.

Further, the gate insulation film 6 on the active regions 1b to 1d may be formed thicker on the upper surfaces of the active regions 1b to 1d than on the side surfaces by the method described in the first preferred embodiment to configure the MOS transistor TR2, driver transistor DTR and the like to have the double-gate structure.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device having a memory cell area in which a plurality of memory cells are formed and a logic circuit area in which a logic circuit is formed, said semiconductor device comprising:
a semiconductor substrate;
an isolation insulation film provided in an upper surface of said semiconductor substrate to define a first active region in said semiconductor substrate within said memory cell area and second and third active regions in said semiconductor substrate within said logic circuit area; and
first to third MOS transistors provided in said first to third active regions, respectively, wherein
as viewed from above, a dimension of said first active region along a gate width of said first MOS transistor and a dimension of said second active region along a gate width of said second MOS transistor are smaller than a dimension of said third active region along a gate width of said third MOS transistor,
as viewed from above, said dimension of said second active region is not greater than said dimension of said first active region,
in said isolation insulation film within said memory cell area, a first-active-region peripheral portion provided around said first active region has an upper surface positioned below an upper surface of said first active region, and a first gate electrode is formed on an upper surface of part of said first active region and side surfaces of said part of said first active region facing each other along the gate width of said first MOS transistor, said part of said first active region projecting upward from the upper surface of said first-active-region peripheral portion, a first gate insulation film being interposed between said first gate electrode and the upper and side surfaces of said part of said first active region,
in said isolation insulation film within said logic circuit area, a second-active-region peripheral portion provided around said second active region has an upper surface positioned below an upper surface of said second active region, and a second gate electrode is formed on an upper surface of part of said second active region and side surfaces of said part of said second active region facing each other along the gate width of said second MOS transistor, said part of said second active region projecting upward from the upper surface of said second-active-region peripheral portion, a second gate insulation film being interposed between said second gate electrode and the upper and side surfaces of said part of said second active region, and
the upper surface of said first-active-region peripheral portion and the upper surface of said second-active-region peripheral portion are positioned below an upper surface of a third-active-region peripheral portion provided around said third active region in said isolation insulation film within said logic circuit area.

2. The semiconductor device according to claim 1, wherein
as viewed from above, said dimension of said first active region along the gate width of said first MOS transistor and said dimension of said second active region along the gate width of said second MOS transistor are set not greater than 50 nm.

3. A semiconductor device comprising:
a semiconductor substrate;
an isolation insulation film provided in an upper surface of said semiconductor substrate to define first and second active regions in said semiconductor substrate; and
first and second MOS transistors provided in said first and second active regions, respectively, wherein
in said isolation insulation film, a first-active-region peripheral portion provided around said first active region has an upper surface positioned below an upper surface of said first active region, and a first gate electrode is formed on an upper surface of part of said first active region and side surfaces of said part of said first active region facing each other along a gate width of said first MOS transistor, said part of said first active region projecting upward from the upper surface of said first-active-region peripheral portion, a first gate insulation film being interposed between said first gate electrode and the upper and side surfaces of said part of said first active region, and
in said isolation insulation film, a second-active-region peripheral portion provided around said second active region has an upper surface positioned below an upper surface of said second active region and the upper surface of said first-active-region peripheral portion, and a second gate electrode is formed on an upper surface of part of said second active region and side surfaces of said part of said second active region facing each other along a gate width of said second MOS transistor, said part of said second active region projecting upward from the upper surface of said second-active-region peripheral portion, a second gate insulation film being interposed between said second gate electrode and the upper and side surfaces of said part of said second active region.

4. The semiconductor device according to claim 3, wherein
as viewed from above, a dimension of said first active region along the gate width of said first MOS transistor and a dimension of said second active region along the gate width of said second MOS transistor are set not greater than 50 nm.

5. A semiconductor device having a first area in which a plurality of SRAM memory cells are formed and a second area in which an interface circuit is formed, said semiconductor device comprising:
a semiconductor substrate;
an isolation insulation film provided in an upper surface of said semiconductor substrate to define a first active region in said semiconductor substrate within said first area and a second active region in said semiconductor substrate within said second area; and
first and second MOS transistors provided in said first and second active regions, respectively, wherein
in said isolation insulation film within said first area, a first-active-region peripheral portion provided around said first active region has an upper surface positioned below an upper surface of said first active region, and a first gate electrode is formed on an upper surface of part of said first active region and side surfaces of said part of said first active region facing each other along a gate width of said first MOS transistor, said part of said first active region projecting upward from the upper surface of said first-active-region peripheral portion, a first gate insulation film being interposed between said first gate electrode and the upper and side surfaces of said part of said first active region,
a second gate electrode is formed on an upper surface of said second active region with a second gate insulation film interposed therebetween, and
the upper surface of said first-active-region peripheral portion is positioned below an upper surface of a second-active-region peripheral portion provided around said second active region in said isolation insulation film within said second area.

6. A method of manufacturing a semiconductor device having a memory cell area in which a plurality of memory cells are formed and a logic circuit area in which a logic circuit is formed, said method comprising the steps of:
(a) forming an isolation insulation film in an upper surface of a semiconductor substrate to define a first active region in said semiconductor substrate within said memory cell area and second and third active regions in said semiconductor substrate within said logic circuit area;
(b) etching down an upper surface of a first-active-region peripheral portion provided around said first active region in said isolation insulation film within said logic circuit area to be positioned below an upper surface of said first active region, as well as etching down an upper surface of a second-active-region peripheral portion provided around said second active region in said isolation insulation film within said logic circuit area to be positioned below an upper surface of said second active region, without etching down an upper surface of a third-active-region peripheral portion provided around said third active region in said isolation insulation film within said logic circuit area; and
(c) forming first to third MOS transistors in said first to third active regions, respectively, after said step (b), wherein
in said step (a), said isolation insulation film is formed such that a dimension of said first active region in a first direction in which a gate width of said first MOS transistor is to extend and a dimension of said second active region in a second direction in which a gate width of said second MOS transistor is to extend are smaller than a dimension of said third active region in a third direction in which a gate width of said third MOS transistor is to extend and such that said dimension of said second active region is not greater than said dimension of said first active region, and
in said step (c), a first gate electrode is formed on an upper surface of part of said first active region and side surfaces of said part of said first active region facing each other in said first direction, said part of said first active region projecting upward from the upper surface of said first-active-region peripheral portion by the execution of said step (b), a first gate insulation film being interposed between said first gate electrode and the upper and side surfaces of said part of said first active region, and a second gate electrode is formed on an upper surface of part of said second active region and side surfaces of said part of said second active region facing each other in said second direction, said part of said second active region projecting upward from the upper surface of said second-active-region peripheral portion by the execution of said step (b), a second gate insulation film being interposed between said second gate electrode and the upper and side surfaces of said part of said second active region.

7. The method according to claim 6, wherein
said step (a) includes the steps of:
(a-1) forming a mask film on said semiconductor substrate;
(a-2) forming a resist having a predetermined resist pattern on said mask film;
(a-3) conducting anisotropic etching on said mask film using said resist as a mask, thereby forming an opening in said mask film;
(a-4) removing said resist after said step (a-3);
(a-5) conducting isotropic etching on said mask film after said step (a-4), thereby extending said opening;
(a-6) removing a portion exposed by said opening after said step (a-5), thereby forming a trench in said semiconductor substrate; and
(a-7) filling said trench with said isolation insulation film.

8. A method of manufacturing a semiconductor device, comprising the steps of:
(a) forming an isolation insulation film in an upper surface of a semiconductor substrate to define first and second active regions in said semiconductor substrate;
(b) etching down an upper surface of a first-active-region peripheral portion provided around said first active region in said isolation insulation film to be positioned below an upper surface of said first active region, as well as etching down an upper surface of a second-active-region peripheral portion provided around said second active region in said isolation insulation film to be positioned below an upper surface of said second active region and the upper surface of said first-active-region peripheral portion; and
(c) forming first and second MOS transistors in said first and second active regions, respectively, after said step (b), wherein
in said step (c), a first gate electrode is formed on an upper surface of part of said first active region and side surfaces of said part of said first active region facing each other along a gate width of said first MOS transistor, said part of said first active region projecting upward from the upper surface of said first-active-region peripheral portion by the execution of said step (b), a first gate insulation film being interposed between said first gate electrode and the upper and side surfaces of said part of said first active region, and a second gate electrode is formed on an upper surface of part of said second active region and side surfaces of said part of said second active region facing each other along a gate width of said second MOS transistor, said part of said second active region projecting upward from the upper surface of said second-active-region peripheral portion by the execution of said step (b), a second gate insulation being interposed between said second gate electrode and the upper and side surfaces of said part of said second active region.

9. The method according to claim 8, wherein
said step (a) includes the steps of:
(a-1) forming a mask film on said semiconductor substrate;
(a-2) forming a resist having a predetermined resist pattern on said mask film;
(a-3) conducting anisotropic etching on said mask film using said resist as a mask, thereby forming an opening in said mask film;
(a-4) removing said resist after said step (a-3);
(a-5) conducting isotropic etching on said mask film after said step (a-4), thereby extending said opening;
(a-6) removing a portion exposed by said opening after said step (a-5), thereby forming a trench in said semiconductor substrate; and
(a-7) filling said trench with said isolation insulation film.

10. A method of manufacturing a semiconductor device having a first area in which a plurality of SRAM memory cells are formed and a second area in which an interface circuit is formed, said method comprising the steps of:
(a) forming an isolation insulation film in an upper surface of a semiconductor substrate to define a first active region in said semiconductor substrate within said first area and a second active region in said semiconductor substrate within said second area;
(b) etching down an upper surface of a first-active-region peripheral portion provided around said first active region in said isolation insulation film within said first area to be positioned below an upper surface of said first active region, without etching down an upper surface of a second-active-region peripheral portion provided around said second active region in said isolation insulation film within said second area; and
(c) forming first and second MOS transistors in said first and second active regions, respectively, after said step (b), wherein
in said step (c), a first gate electrode is formed on an upper surface of part of said first active region and side surfaces of said part of said first active region facing each other in a direction in which a gate width of said first MOS transistor is to extend, said part of said first active region projecting upward from the upper surface of said first-active-region peripheral portion by the execution of said step (b), a first gate insulation film being interposed between said first gate electrode and the upper and side surfaces of said part of said first active region, and a second gate electrode is formed on the upper surface of said second active region with a second gate insulation film interposed therebetween.

11. The method according to claim 10, wherein
said step (a) includes the steps of:
(a-1) forming a mask film on said semiconductor substrate;
(a-2) forming a resist having a predetermined resist pattern on said mask film;
(a-3) conducting anisotropic etching on said mask film using said resist as a mask, thereby forming an opening in said mask film;
(a-4) removing said resist after said step (a-3);
(a-5) conducting isotropic etching on said mask film after said step (a-4), thereby extending said opening;
(a-6) removing a portion exposed by said opening after said step (a-5), thereby forming a trench in said semiconductor substrate; and
(a-7) filling said trench with said isolation insulation film.
